(19) United States
(12) Patent Application Publication
(10) Pub. No.: US 2012/0074558 A1
(43) Pub. Date: Mar. 29, 2012

(54) Circuit Board Packaged with Die through Surface Mount Technology

(75) Inventors: Hsuan Yu LU, Taoyuan County (TW); Tse Ming CHU, Taipei City (TW); Kuei-Wu CHU, Taoyuan County (TW)

(73) Assignee: MAO BANG ELECTRONIC CO., LTD., Taoyuan County (TW)

(21) Appl. No.: 13/041,711

(22) Filed: Mar. 7, 2011

(30) Foreign Application Priority Data
Sep. 29, 2010 (TW) 099218813

(51) Int. Cl. H01L 23/488

(52) U.S. Cl. 257/693; 257/E23.023

(57) ABSTRACT

A package of a circuit board and a die are packed through surface mount technology (SMT). The shortest circuit is formed with at a low cost. Thus, the package can work in high speed and high frequency applications.

### TECHNICAL FIELD OF THE DISCLOSURE

The present disclosure relates to a package of circuit board and die; more particularly, relates to forming the shortest circuit with a low cost for the package of the circuit board and the die to work in high speed and high frequency applications.

### DESCRIPTION OF THE RELATED ART

As shown in FIG. 2, a package comprises a circuit board 3 and a die 4, where the circuit board 3 has a circuit layout 31 at a bottom surface of the circuit board 3; the circuit board 3 has at least one hole 32; the circuit layout 31 has a plurality of tin balls 33 at a bottom surface of the circuit layout 31; the die 4 is connected on a surface of the circuit board 1; the die 4 has an input/output (I/O) point 41 at a bottom surface of the die 4; the I/O point 41 is connected with the circuit layout 31 through gold wires 42 extending out of the hole 32 from the bottom surface of the die 4; and a protection paste 43 is filled into the hole 32 and protects the gold wires 42 with the protection paste 43. Thus, the circuit board 3 and the die 4 are packaged.

However, because the circuit board 3 and the die 4 are packaged with gold wires 42 having the protection paste filled for protection, time spent for packaging becomes long with complex procedure and expensive cost. Moreover, the gold wires 42 for connection make a package circuit long and thus make a working speed and a working frequency low. Hence, the prior art does not fulfill all users' requests on actual use.

### SUMMARY OF THE DISCLOSURE

The main purpose of the present disclosure is to form a shortest circuit with low cost for a package of a circuit board and a die to work in a high speed and a high frequency.

To achieve the above purpose, the present disclosure is a circuit board packaged with a die through surface mount technology (SMT), comprising a circuit board and a die, where the circuit board has a circuit layout layer on a surface; where the die is connected with the circuit board on a surface of the circuit board; where the die has an I/O point on a surface; where the die has a connecting wire layer on the surface of the die having the I/O point; where the connecting wire layer has a plurality of pads; where the pads are connected with the circuit layout layer; and where the die is thus connected with the circuit layout layer of the circuit board through SMT with coordination of the pads. Accordingly, a novel circuit board connected with a die through SMT is obtained.

### BRIEF DESCRIPTIONS OF THE DRAWINGS

The present disclosure will be better understood from the following detailed description of the preferred embodiment according to the present disclosure, taken in conjunction with the accompanying drawings, in which

FIG. 1 is the sectional view showing the preferred embodiment according to the present disclosure; and

FIG. 2 is the sectional view of the prior art.

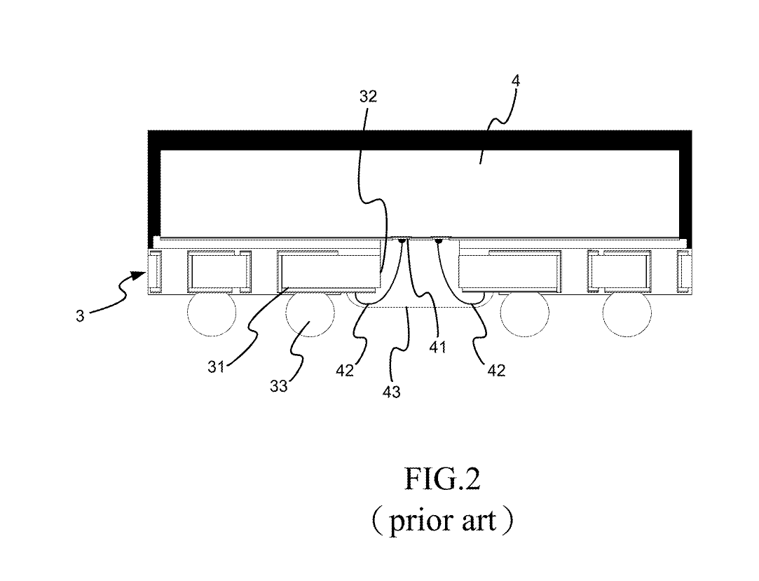

### DESCRIPTION OF THE PREFERRED EMBODIMENT

The following description of the preferred embodiment is provided to understand the features and the structures of the present disclosure.

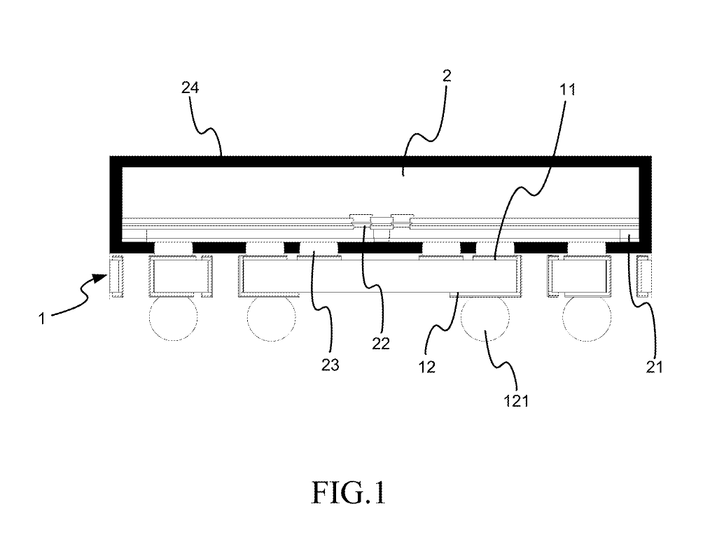

Please refer to FIG. 1, which is a sectional view showing a preferred embodiment according to the present disclosure. As shown in the figure, the present disclosure is a circuit board packaged with a die through surface mount technology (SMT), comprising a circuit board 1 and a die 2.

The circuit board 1 has a first circuit layout layer 11 on a first surface and a second circuit layout layer 12 on a second surface, where the second circuit layout layer 12 has a plurality of connecting materials 121 and the connecting materials 121 are tin balls.

The die 2 is a double-data-rate (DDR) chip. The die 2 is connected with the circuit board 1 on a surface of the circuit board 1. The die 2 has an input/output (I/O) point 21. The surface of the die 2 having the I/O point 21 has a connecting wire layer 22. The connecting wire layer 22 has a plurality of pads 23 to be connected with the first circuit layout layer 11 through the plurality of pads 23. The pads 23 are tin balls. Furthermore, the die 2 is covered with a shell 24 on an outside surface of the die 2 for protecting the die 2; and, the pads 23 are exposed out of the shell 24.

Thus, a novel circuit board packaged with a die through SMT is obtained.

On fabricating the present disclosure, the pads 23 on the connecting wire layer 22 of the die 2 are correspondingly deposed on the first circuit layout layer 11 of the circuit board 1. Then, through SMT, the die 2 is packaged on the first circuit layout layer 11 of the circuit board 1 with coordination of the pads 23. Then, according to requirement, by using connecting materials 121 of the second circuit layout layer 12 on the second surface, the packaged of the circuit board 1 and the die 2 is connected with other equipment (not shown in the figure). Thus, a shortest circuit is formed with low cost for the package of the circuit board 1 and the die 2 to work in a high speed and a high frequency.

To sum up, the present disclosure is a circuit board packaged with a die through SMT, where a shortest circuit is formed with low cost for a package of a circuit board and a die to work in a high speed and a high frequency.

The preferred embodiment herein disclosed is not intended to unnecessarily limit the scope of the disclosure. Therefore, simple modifications or variations belonging to the equivalent of the scope of the claims and the instructions disclosed herein for a patent are all within the scope of the present disclosure.

What is claimed is:

1. A circuit board packaged with a die through surface mount technology (SMT), comprising:
a circuit board, said circuit board having a circuit layout layer on a first surface of said circuit board; and
a die, said die being connected with said circuit board on said first surface of said circuit board, said die having an input/output (I/O) point on a surface of said die, said die having a connecting wire layer on said surface of said die having said I/O point, said connecting wire layer having a plurality of pads, said pads being connected with said circuit layout layer,
wherein said die is packaged on said circuit layout layer of said circuit board through SMT with coordination of said pads.

2. The circuit board according to claim 1,
wherein said circuit board has a second circuit layout layer on a second surface of said circuit board; and
wherein said second circuit layout layer has a plurality of connecting materials.

3. The circuit board according to claim 2,
wherein said connecting materials are tin balls.

4. The circuit board according to claim 1,
wherein said die is a double-data-rate (DDR) chip.

5. The circuit board according to claim 1,
wherein said die is covered with a shell on an outside surface of said die; and
wherein said pads are exposed out of said shell.

6. The circuit board according to claim 1,
wherein said pads are tin balls.
